(19) United States
(12) Patent Application Publication
(10) Pub. No.: US 2016/0155876 A1
(43) Pub. Date: Jun. 2, 2016

(54) MULTI-STEP HOLOGRAPHIC ENERGY CONVERSION DEVICE AND METHOD

(71) Applicant: Alfred JOST, Mesa, AZ (US)

(72) Inventor: Alfred JOST, Mesa, AZ (US)

(21) Appl. No.: 15/018,488

(22) Filed: Feb. 8, 2016

Related U.S. Application Data
(63) Continuation-in-part of application No. 14/195,448, filed on Mar. 3, 2014.
Application No. 14/195,448 is a continuation-in-part of application No. 14/126,958, filed on Dec. 17, 2013, now abandoned.
(60) Provisional application No. 61/501,211, filed on Jun. 25, 2011.

(51) Int. Cl. H01L 31/054

(52) U.S. Cl. CPC H01L 31/0547

(57) ABSTRACT

An energy conversion device includes a multi-step holographic optical element arranged between a transparent cover and a first solar cell. The multi-step holographic optical element is configured to concentrate a portion of a first component of impinging electromagnetic radiation onto the first solar cell. The solar cell is configured to convert the first component of impinging electromagnetic radiation into electrical energy.

### TECHNICAL FIELD

The present disclosure generally relates to a converting electromagnetic radiation into electrical energy, and more particularly relates to the use of solar panels or modules to generate electricity from light energy.

### BACKGROUND

In the field of solar energy, the principle of converting solar radiation into electrical current has been known and used for at more than fifty years. This conversion of light energy into electrical current has been and remains enabled through the use of solar cells that include silicon, conventionally monocrystalline or multi-crystalline silicon. The power of these solar cells is relatively low, however, as they only convert a limited spectrum of impinging radiation into electrical current.

Great success has been achieved in recent years with high power photovoltaic cells made of high-quality semiconductor connections (III-IV semiconductor material) such as gallium arsenide to accomplish significantly higher efficiency with about 40% conversion of the solar radiation. This is largely accomplished by concentrating sunlight onto a very small surface area. More particularly, it is a common practice to gather and concentrate sunlight reaching a given photovoltaic cell so that such extremely large areas of semiconductor material need not be employed as would necessarily be the case without such a gathering and concentrating system. Common past gathering systems included optical systems in which lens systems concentrated light and focused it on a given photovoltaic cell. A plurality of solar units allows for the economical use of a photovoltaic system of this type.

However, such a lens system, utilized to impinge sunlight directly on solar cells, was and is relatively expensive and large. Conventional systems predominantly work by incorporating relatively large Fresnel lenses with a relatively large focal length, and this in turn produces modules that are quite thick. These large structures result in solar power units that are very heavy.

Accordingly, it is desirable to provide an energy conversion device or solar module that is able to utilize a large range of wavelengths of light and in turn have improved overall efficiency. In addition, it is desirable to provide an energy conversion device that incorporates fewer and smaller components in order to reduce the module's size and manufacturing costs. Furthermore, other desirable features and characteristics of the present disclosure will become apparent from the subsequent detailed description of the disclosure and the appended claims, taken in conjunction with the accompanying drawings and this background of the disclosure.

### SUMMARY

In one example, an energy conversion device is provided. The energy conversion device includes a multi-step or multi-level holographic optical element arranged between a transparent cover and a first solar cell. The multi-step holographic optical element is configured to concentrate a portion of a first component of impinging electromagnetic radiation onto the first solar cell. The solar cell is configured to convert the first component of impinging electromagnetic radiation into electrical energy.

A method of making an energy conversion device is also provided. According to the method, a multi-step holographic optical element is printed directly onto first surface of a transparent in a pattern that forms a holographic lens. The holographic lens is arranged between the glass slab and a first solar cell. The first solar cell is arranged such that at least one solar cell stripe of the first solar cell is arranged between the holographic lens and an electrical connector, the electrical connector being electrically connected to the at least one solar cell stripe.

### BRIEF DESCRIPTION OF THE DRAWINGS

Exemplary descriptions of the solar module or energy conversion device and methods of producing an energy conversion device will be apparent from the following description and the drawings appended hereto, wherein like numerals denote like elements.

FIG. 1 is a schematic diagram representing the manner by which desirable wavelengths of sunlight are focused with high efficiency onto a solar cell according to an exemplary embodiment.

FIG. 2 is a schematic diagram representing the manner by which undesirable wavelengths of sunlight are focused so they do not impinge onto a solar cell according to another exemplary embodiment.

FIG. 3 is a schematic diagram representing the manner by which desirable and undesirable wavelengths of sunlight are respectively focused with high efficiency onto a solar cell, or focused away from a solar cell and reflected away from the energy conversion device according to an embodiment.

FIG. 4 is a schematic diagram representing a cross-sectional profile showing the structure of a multi-step or multi-level diffractive optical element of a hologram of an energy conversion device according to one embodiment.

FIG. 5 shows an enlarged portion of the multi-step diffractive optical element of FIG. 4.

FIG. 6 shows a schematic diagram of a top view of a solar module with multiple holographic optic strips according to an embodiment.

FIG. 7 is a schematic diagram representing the manner by which desirable wavelengths of sunlight are focused with high efficiency onto a metal wrap through (MWT) solar cell according to an exemplary embodiment.

FIG. 8 is a schematic diagram representing the manner by which desirable wavelengths of sunlight are focused with high efficiency onto an interdigitated back contact solar cell (IBC).

### DETAILED DESCRIPTION

The following detailed description of the disclosure is merely exemplary in nature and is not intended to be limiting of the energy conversion device or the application and uses of the solar module. Furthermore, there is no intention to be bound by any theory presented in the preceding background or the following detailed description.

In this description, a solar panel and a solar module are interchangeable terms, both being defined as a structure that includes a plurality of solar cells, with the wattage produced being directly proportionally related to the number of solar cells included in the solar module. The solar module may also include a frame, strings that connect the solar cells, a back sheet, a glass slab, and optics.

One embodiment is directed to a solar module that includes solar cells with which electrical current is produced by the concentration of light using a lens, in close proximity with the solar cells, that includes silicon or another appropriate semiconductor material. The optical lens is a unique holographic element that function as a lens and is adapted to selectively concentrate, deflect, and focus different components of the solar spectrum, each different light component being treated differently according to the wavelengths of light that are included in that light component.

As will be discussed hereinafter, the novel holographic deflecting lens and its ability to concentrate, focus, and deflect different wavelengths of light in a predetermined manner enables the use of a minimal amount of silicon and other semiconductor material. In fact, a reduction of up to 90% compared to conventional solar panels is enabled by the present disclosure, while producing high amounts of electrical energy. In another embodiment, a reduction of a minimum of 90% compared to conventional solar panels is enabled by the present disclosure, while still producing high amounts of electrical energy. The efficient use of photovoltaic cells allows for production of conventionally sized solar modules that require significantly less semiconductor material.

Furthermore, by employing the new holographic deflecting lens as a means for producing electrical energy from solar radiation, the percentage of the solar radiation that is used to generate electrical energy is greatly improved. Because the lens is able to concentrate, focus, and deflect different light components for different purposes, efficiencies of up to 92% of all solar radiation being converted to electricity using the solar module of the present disclosure are realized.

Additionally, as will be seen in conjunction with the figures, the novel holographic deflecting lens makes possible a solar module in which a very small distance is needed between the lens and the silicon or other semiconductor material. This in turn imparts a very small overall module height and cost friendly production. Consequently, compared to traditional solar panels, a significantly reduced cost of constructing and transporting is achieved.

There is also the advantage that the solar modules can be used on the standard single axis tracking system. Concentrator solar modules generally track in two directions, the first direction being daylight, or movement of the sun, and the second direction being the seasonal or summer-winter position of the sun. The solar module of the present disclosure includes a holographic deflecting lens that adapts to the seasonal or summer-winter variance. Accordingly, only the daylight, or movement of the sun, needs to be tracked to optimize electricity output.

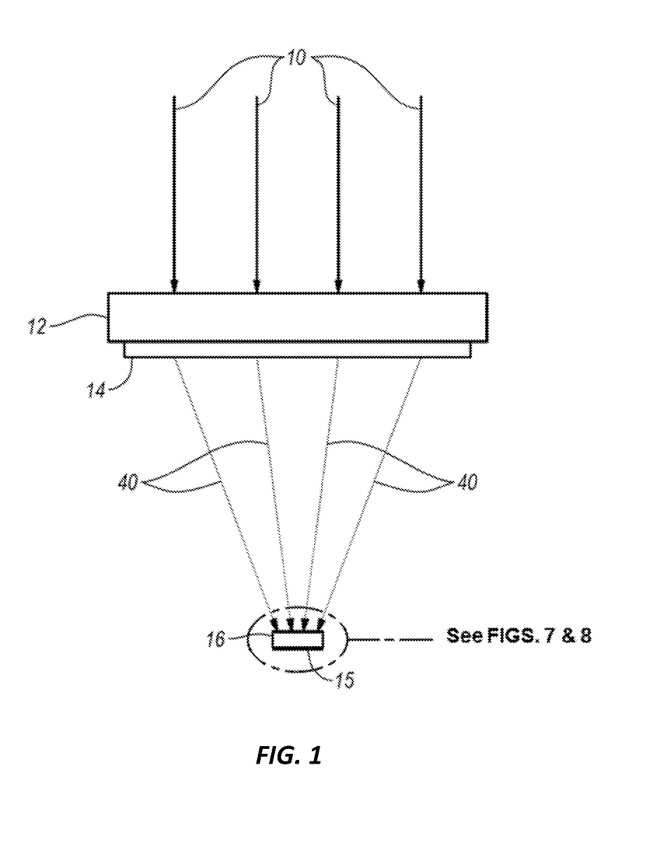

Turning now to FIG. 1, a schematic diagram is used to depict the manner by which desirable wavelengths 40 of sunlight 10 are focused with high efficiency onto a solar cell 16 in a solar module according to an exemplary embodiment of the present disclosure. As depicted in FIG. 1, a sunlight component of desirable wavelengths 40, for example, light in the wavelengths ranging between about 380 and about 1150 nm (including visible light and near infrared (NIR) light), or between about 500 and about 750 nm, or between 500 and 600 nm, or between 510 and 580 nm, is bent and deflected when it passes through a holographic deflecting lens 14 that is formed directly on a glass slab 12. The visible sunlight component 10 passes through the glass slab 12, which supports the lens 14. As depicted in the figures, the lens 14 is formed on the interior side of the glass slab 12 instead of the exterior side. Consequently, the glass slab 12 functions as a cover and protection for the lens 12 in the solar module.

The lens 14 is adapted to deflect only the sunlight component of desirable wavelengths 40 in a manner whereby it is concentrated and focused with high efficiency onto a photovoltaic solar cell 16. The solar cell 16 is made of a suitable semiconductor material such as mono- or polycrystalline silicon or silicon with a high purity (at least 99.99999%).

The solar cell 16 is part of an array of stripes of the silicon, or other suitable material, with each stripe having a width of 1 mm to 10 mm. The array of stripes may be electrically connected by back contact 15, which serves as an electrical contact arranged on a side of the solar cell 16 that is opposite from lens 14. Thus, solar cell 16 may be a back contact solar sell, having contacts that are formed on the back of the silicon solar cell strips. Such an arrangement ensures a low level of optical shading due to electrical wires, and results in high efficiency. The back contact 15 is a connection that may connect the cells in series or parallel, depending on the voltage output. However, although solar cell 16 may be a back contact solar cell, in another embodiment, the solar cell may be a standard crystalline solar cell or a front contact solar cell, being that at least some of the electrical leads for the solar cell are on the same side of the solar cell as the lens 14 is arranged, or at least some of the electrical contacts are arranged between the solar cell and lens 14.

Because only the desirable sunlight component 40 is concentrated and focused onto the solar cell 16, zero, or at least a reduced portion of desirable component 40 of sunlight 10 passes through the lens 14 is unused. Instead, all of the sunlight, or in another embodiment substantially all (i.e. >99%) of the sunlight, from the desirable component 40 that passes through the lens 14 is concentrated and focused onto the silicon solar cell 16 and is converted into electrical current. According to one embodiment, the inherent translucency of even the best quality glass slab and lens material causes some sunlight not to pass through the lens 14, causing a loss of 8 to 10% of the sunlight. However, the entire sunlight component 10 that does pass through both the glass and lens is converted into electrical current.

Similarly, more than 90% of the sunlight that is not part of the sunlight component 10 is directed away from the solar cell 16. The following figures will better explain how non-visible sunlight may be focused away from the solar cell 16 and either reflected away, concentrated and focused onto another area. In these cases, the lens 14 according to one embodiment accomplishes the same efficiencies with other sunlight components as just described in relation to the sunlight component 10.

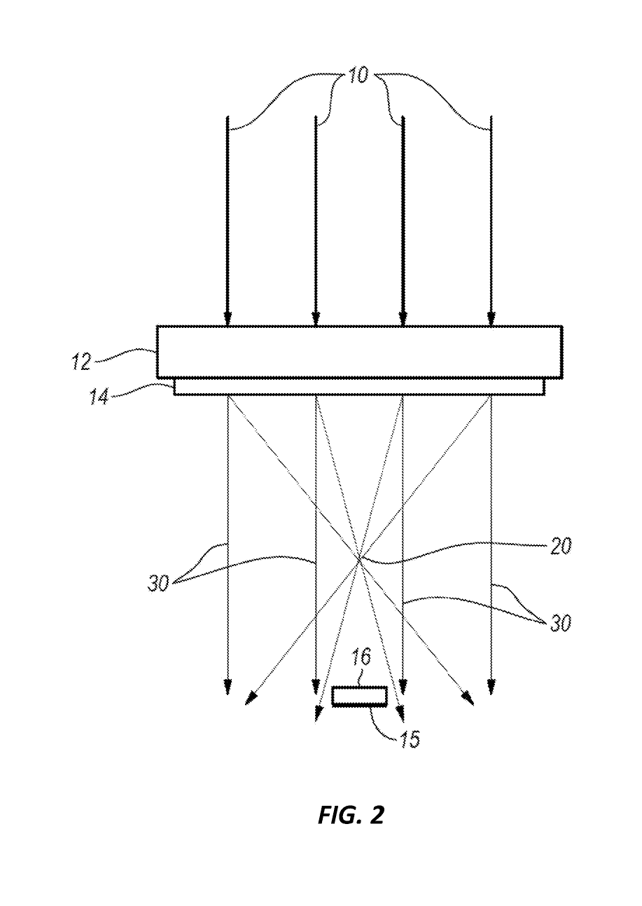

FIG. 2 represents the manner by which an undesirable sunlight component 20 is of sunlight 10 is focused so that light having undesirable wavelengths 20 does not impinge onto the silicon solar cell 16 according to an exemplary embodiment of the present disclosure. Undesirable light 20 in this respect may be light having wavelengths outside of the visible spectrum or near infrared spectrums. Undesirable light in this respect may be light having wavelengths greater than 750 nm. While the visible sunlight component 40 is bundled and captured by way of deflecting, concentrating, and focusing it on the silicon solar cell 16, the undesirable light component 20 passes through the glass slab 12 and the holographic deflecting lens 14 supported thereon, which is adapted to bend and deflect the undesirable light component 20 away from the cell 16.

As depicted in FIG. 2, the deflecting characteristic of the lens 14 causes the undesirable light component 20 to do two things. On one hand, much or most of the light from the undesirable light component 20 passes straight through the structure so it does not impinge on the silicon solar cell 16. On the other hand, a smaller part of the light from the undesirable light component 20 is focused, but the focus is directed to a position away from the cell 16. According to an exemplary embodiment, infrared light is focused between the silicon solar cell 16 and the holographic deflecting lens 14. After reaching their focal point, the infrared light rays form a divergent bundle, with the result that at the board level, on which the silicon solar cell 16 is fixed, the rays are very disperse. Consequently, the undesirable light component 20, including infrared light, is focused away from the silicon photovoltaic cell 16 such that very little if any of the light from the undesirable light component 20 impinge on the cell 16.

The undesirable light component 20 may be reflected by way of mirrors adjacent to the cell 16. However, as will be described in detail, in another embodiment of the disclosure the infrared light from the undesirable light component 20 is bent and deflected by the holographic deflecting lens 14 in a manner whereby it is focused onto a germanium-coated silicon solar cell or germanium thermophotovoltaic cell that is part of a system adapted to convert heat differentials to electricity via photons. The germanium-coated silicon solar sell or gemanium thermophotovoltaic cell may also be a back contact solar cell. Further, in one embodiment the solar cell may comprise silicon. However, one or more other cell materials may also be used for the cell, such as GaAs, CdS, and CdSe instead of or together with Ge.

Accordingly, the holographic deflecting lens 14 is uniquely adapted to selectively concentrate, deflect, and focus different components 40, 20 of the solar spectrum. For purposes of clarification, it is to be understood that the lens 14 may be a hologram that selectively bends each different light component 40, 20 differently according to the wavelengths of light that are included in that light component. More particularly, the structures that compose the lens 14 are formed and adapted with precision to produce both an angle of deflection and a deflection efficiency that depend on the wavelength of sunlight 10 impinging on the lens 14. This enables the need for a minimal amount of silicon or other solar cell material while producing high amounts of electrical energy.

According to one embodiment, the impinging sunlight 10 also includes undesirable light 30 that includes wavelengths in the ultraviolet range. In this embodiment, the holographic deflecting lens 14 is adapted to treat ultraviolet light having wavelengths below about 380 nm, or including light having wavelengths below about 500 nm, in a somewhat similar manner as the infrared light discussed previously. On one hand, much or most of the ultraviolet light from the undesirable light component 30 runs straight through the structure so it does not impinge on the silicon solar cell 16. On the other hand, a smaller part of the ultraviolet light from the undesirable light component 30 is focused, but the focus is again directed to a position away from the cell 16. According to an exemplary embodiment, ultraviolet light is focused beyond the silicon solar cell 16 with the result that at the board level, on which the silicon solar cell 16 is fixed, the rays are disperse. Consequently, the undesirable light component, including ultraviolet light 30, is focused away from the silicon photovoltaic cell 16 such that very little if any of the light from the undesirable light component 30 impinge on the cell 16.

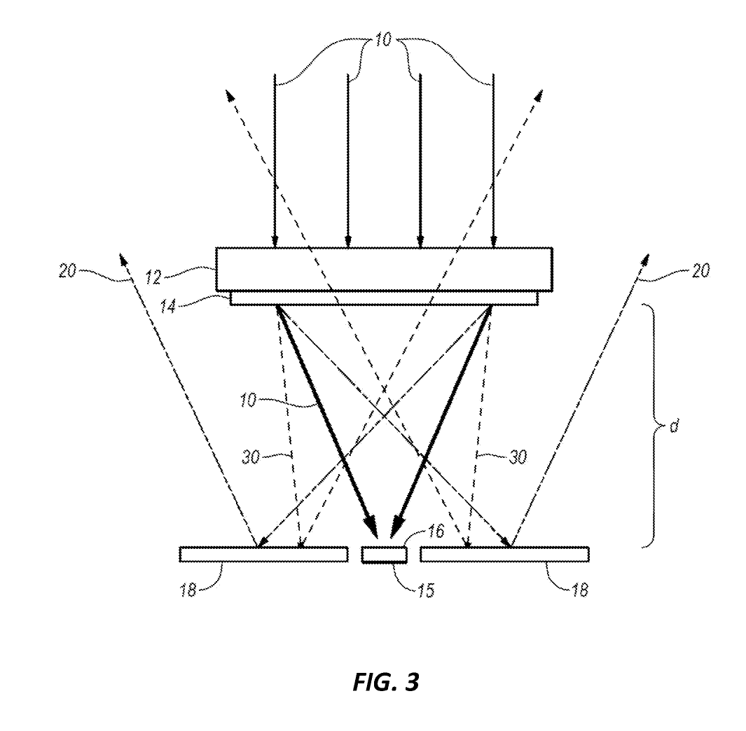

Turning now to FIG. 3, a schematic diagram is used to represent the manner by which desirable and undesirable wavelengths of sunlight are respectively focused with high efficiency onto the solar cell 16, or focused away from the solar cell 16 and reflected away from the solar module according to this embodiment. As depicted, the desirable light 10 is bent and focused onto the solar cell 16. At the same time, the undesirable light including infrared light 20 (designated by the . . - pattern) and the ultraviolet light 30 (designated by the - - pattern) are respectively focused before and after the solar cell 16 in order to avoid impinging on the cell 16.

To ensure that the light rays from the undesirable light component 20, 30 are reflected away from the cell 16, a mirror element 18 including a unique assembly of mirrors is utilized. The mirror element 18 includes a mirror coating that may be formed adjacent to the cell 16. According to one embodiment, the mirror coating is one layer, or a plurality of layers formed on the same board on which the solar cell 16 is fixed. The mirror element may be formed from any suitable light reflective material such as copper, tin, or tin-plated copper.

In one embodiment, the hologram is a holographic optic that is composed of or includes a ultraviolet (UV) curable material. The UV-curable material may be a lacquer, polymer, or resin. The UV curable material may be a lacquer material. The material of the holographic optic may be a temperature-resistant material, and preferably is a material that can withstand elevated temperatures for extended amounts of time. According to one embodiment, the material of the holographic optic can withstand a temperature of up to 160° Celsius (C). In another embodiment, the material of the holographic optic can withstand a temperature of even greater than 160° C. In an embodiment, the holographic optic is formed of a material that is able to withstand temperatures of −30° to 260° C. The material of the holographic optic may also withstand, for at least a short term, a temperature elevated to an even greater amount. In one embodiment, the material of the holographic optic can withstand a short-term temperature of up to 210° C. In another embodiment, the material of the holographic optic can withstand a short-term temperature of greater than 210° C. In another embodiment, the holographic optic is formed of a material that is able to withstand short and long-term temperatures of −30° to 260° C.

Additionally, the material of the holographic optic may preferably be very scratch resistant. Further, in one embodiment, because the holographic optic is formed on the inside of a cover glass, for example, glass slab 12, the holographic optic may be protected from abrasion and the erosive elements in the environment of the device. That is, the glass slab on which the holographic may be formed, for example, by printing, the glass slab or glass cover may protect the holographic optic, as the holographic element or optic is formed on an inside surface of the glass cover or slab.

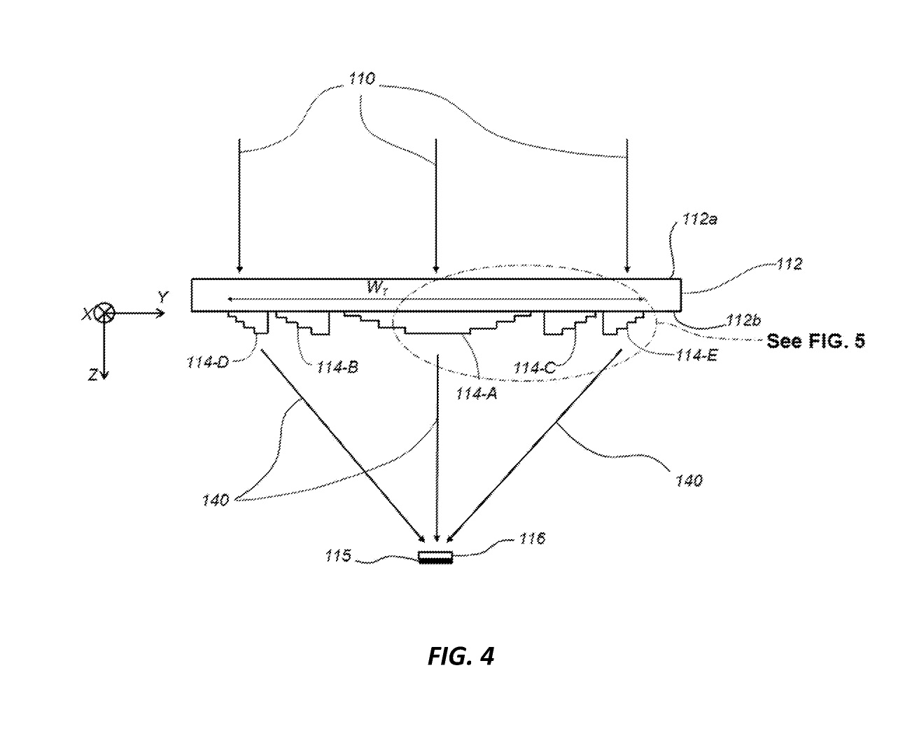

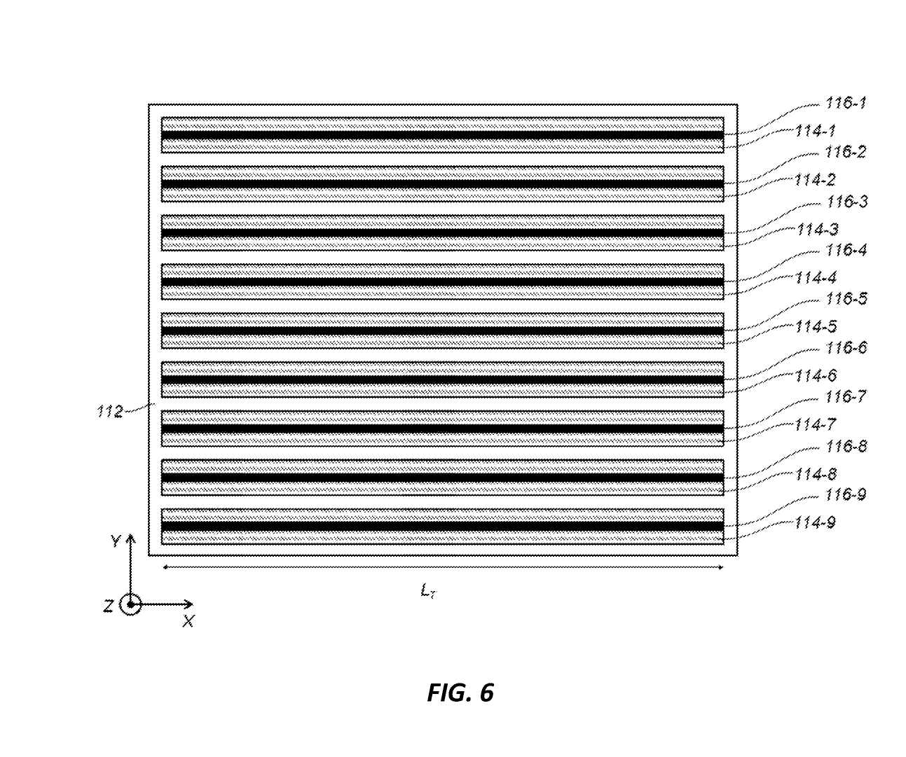

FIG. 4 shows a schematic of a cross-sectional profile showing the structure of a multi-step diffractive holographic optical element of a hologram of an energy conversion device according to one embodiment. FIG. 6 shows a schematic diagram of a top view of a solar module with multiple holographic optic strips according to an embodiment.

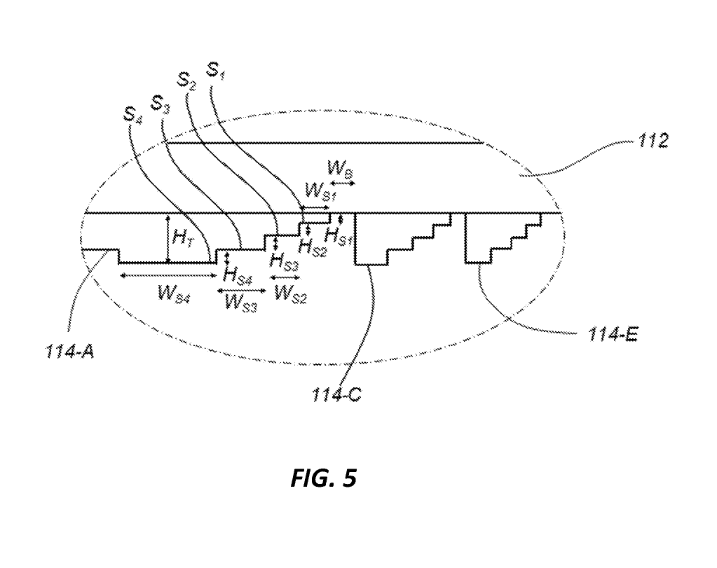

As shown in FIG. 4, sunlight impinges on a first, outer surface 112a of glass slab or cover 112. Cover 112 may be composed of a glass material or some other transparent material, such as quartz, transparent crystalline materials, or transparent polymers, such as polycarbonate. The glass or transparent cover 112 may be 4 to 6 mm thick. On an opposite, inner surface 112b of glass cover 112, a holographic element 114 may be formed. As shown in FIG. 6, the holographic element 114 may include a plurality of holographic stripes 114-1, 114-2, 114-3 . . . 114-9, that are formed to extend in a direction (X-direction) parallel to plurality of solar cells 116-1, 116-2, 116-3 . . . 116-9. The plurality of holographic stripes 114-1, 114-2, 114-3 . . . 114-9 are arranged parallel to each other on the inner surface of cover 112, and are aligned in a second direction (Y-direction). Solar cells 116-1, 116-2, 116-3 . . . 116-9 are also formed and arranged as stripes having a narrower width in the second direction (Y-direction). Although in the schematic diagram of FIG. 6, holographic stripes 114-1, 114-2, 114-3 . . . 114-9 are separated by a distance, analogous to width W_{B} in FIG. 5, in another embodiment, the holographic strips may not be separated by any space but the holographic stripes are arranged such that adjacent holographic stripes are flush against each other. Alternatively, in another embodiment, holographic stripes are arranged on a cover of a device such that some of the holographic stripes that are adjacent to each other are flush against each other while other of the holographic stripes that are adjacent to each other are separated by a distance or width.

In the embodiment shown in FIG. 6, nine holographic stripes 114-1, 114-2, 114-3 . . . 114-9 are formed on the inner surface 112b of cover 112. The nine holographic stripes 114-1, 114-2, 114-3 . . . 114-9 correspond to nine solar cells 116-1, 116-2, 116-3 . . . 116-9. However, more or less holographic strips may be formed or arrange don the surface of cover 112. Each of the nine holographic stripes 114-1, 114-2, 114-3 . . . 114-9 is thus configured to diffract desirable wavelength components 140 of impinging light 110 in the Y-direction to as to be condensed onto the corresponding one of the solar cells 116-1, 116-2, 116-3 . . . 116-9.

As shown in FIG. 4, Each of the holographic stripe is a holographic element that may include a plurality of multi-step structures, including a central multi-step holographic structure 114-A, peripheral multi-step holographic structures 114-D and 114-E, and lateral multi-step holographic structures 114-B and 114-C, the lateral multi-step holographic structures 114-B and 114-C being formed, respectively between the central multi-step holographic structure 114-A and peripheral multi-step holographic structures 114-D and 114-E, respectively. As shown in FIG. 4, central multi-step holographic structure 114-A may be symmetric in the Y-direction about a center portion of the central multi-step holographic structure 114-A. However, in another embodiment, central multi-step holographic structure 114-A is not necessarily symmetric. Similarly, lateral multi-step holographic structures 114-B and 114-C, and peripheral multi-step holographic structures 114-D and 114-E may be symmetric in the Y-direction about a center portion of the central multi-step holographic structure 114-A. However, in another embodiment, lateral multi-step holographic structures 114-B and 114-C, and peripheral multi-step holographic structures 114-D and 114-E may not necessarily be symmetric in the Y-direction about a center portion or another location of the central multi-step holographic structure 114-A.

FIG. 5 shows an enlarged portion of the multi-step diffractive optical element of FIG. 4. FIG. 5 provides further detail regarding the multi-step holographic structures of the holographic element. As shown in FIG. 5, central multi-step holographic structure 114-A may have a plurality of steps S₁, S₂, S₃, and S₄ extending in a direction (Z-direction) perpendicular to the inner surface 112b of cover 112. In the embodiment of FIGS. 4 and 5, central multi-step holographic structure 114-A has a total height H_{T}, incremented from the first step S₁ by a height H_{S1}. Second step S₂ has a height of H_{S2}. Third step S₃ has a height of H_{S3}. And fourth step S₄ has a height of H_{S4}.

In an embodiment, the height of the multi-step structures 114-A, 114-B, 114-C, 114-D, and 114-E is in the nanometer range. For example, in one embodiment, the total height HT may be less than 1200 nanometers. And the height of each step S₁, S₂, S₃, and S₄ for each of the multi-step structures 114-A, 114-B, 114-C, 114-D, and 114-E may be in the range of hundreds of nanometers. In one embodiment, the height of each step S₁, S₂, S₃, and S₄ is about 300 nm.

In one embodiment, the multi-step structures 114-A, 114-B, 114-C, 114-D, and 114-E are printed on the cover glass 112 with a master foil. The master foil may be produced, for example, in an e-beam lithography process to achieve the very small lines necessary in the structure. The smallest line width of the diffractive optic may be 300 nm. The smaller the line width in the edge area of the optic, the grater the focusing/deflection of the light. The transmission or light translucency of the holographic structures may be above 95%.

A concentration factor c of the holographic stripes or hologram may depend on the size of the illuminated area of the holographic optical stripes. A larger illuminated area may lead to a higher concentration or c-factor. The position of the largest concentration also depends on the illuminated area. A minimum concentration factor may be c=10, and a maximum concentration factor may be greater than 40.

Due to the dispersion of light, monochromatic light at different wavelength may be focused at different distances from the holographic structure. In the solar module, the distance from the holographic optical element to the detector material or solar cell is preferably optimized to achieve the highest efficiency out of the solar module. That is, the distance from the holographic optical element to the detector material or solar cell is preferably optimized such that the long-wave visible light is concentrated at a smaller distance to the detector material than the short-wave light.

The holographic optic may select, bend and concentrate the wavelengths of the sunlight. By the structure of the holographic optic, light of desirable wavelengths may be differentiated from undesirable wavelengths from the incoming light or sunlight. What is considered desirable wavelength light may also depend on the detector material of the solar cell. Thus the structure of the holographic element may select the wavelengths that will be bent and concentrated.

Significantly, the desirable wavelengths may be bent and, significantly, not be broken, in a defined direction on the detector material of the solar cell. As used herein, when light is broken, then the whole light spectrum is broken. That is, the full range of wavelength is broken, not only a defined/selected part of it. When light is bent, it is possible to select ranges of the wavelength and to bend them to the preferred direction. So it is possible to exclude certain parts of the light, depending on the structure/coding of the optic.

The undesirable light (of undesirable wavelengths) will be bent away from the detector material. Through the concentration of the desirable wavelengths it is possible to reduce the detector material necessary and at the same time optimize the efficiency of the solar module. For example, if the c-factor of the holographic structures is 40, then the light impinging on a 10,000 cm² can be reduced to a 250 cm² surface of the solar cell. (1/40*10,000 cm²=250 cm²). Whereas, a solar module with a concentration factor of 1 (no concentration) then the solar cell must have the same surface as the impinging surface.

On an area of 1 m², which is 100 cm*100 cm, there may be 40 holographic stripes, each having its respective multi-step holographic structures. The holographic strips may be arranged to extend parallel to each other and parallel to the detector material of each of their respective solar cells. Thus, if the hologram structure has a concentration factor of 40, the detector material of the solar cells, need only have significantly smaller width than the holographic stripes. In the example of the concentration factor of 40, the width of the detector material may only need to be 0.0625 cm, which results in a total detector material of 250 cm². This lends to significantly reduced manufacturing and material costs.

In the case that two or more ranges of desirable wavelengths and two or more detector materials, the holographic optic can select, bend, and concentrate the two or more ranges of wavelengths accordingly.

Further, as shown in FIG. 5, first step S₁ may have a width of W_{S1}. Second step S₂ may have a width W_{S2}. Third step S₃ may have a width of W_{S3}. And fourth step S₄ may have a width of W_{S4}. Additionally, the width between the first step S₁ of central multi-step holographic structure 114-A and a lateral portion or wall of lateral multi-step holographic structure 114-C is W_{B}. In other words, central multi-step holographic structure 114-A may be separated from lateral multi-step holographic structure 114-C in the Y-direction by a distance W_{B}. Lateral multi-step holographic structures 114-B and 114-C, and peripheral multi-step holographic structures 114-D and 114-E, may, similar to central multi-step holographic structure 114-A, be four-step holographic structures, each having steps S₁, S₂, S₃, and S₄, with respective heights and widths.

As shown in FIG. 4, the holographic structures of each of strips 114-1, 114-2 . . . 114-9 may have a combined width of W_{T} in the Y-direction. And as shown in FIG. 6, each of the holographic structures of each of strips 114-1, 114-2 . . . 114-9 may have a total length L_{T} in the X-direction. In an embodiment, the total width W_{T} of the holographic optic is about 2.5 cm or 1 inch. The length L_{T} is adjustable to accommodate the length of the device or module.

The material from which the holographic structures is formed may be, according to an embodiment, a UV-curable polymer, lacquer that is long term temperature resistant. The UV lacquer may be a 100% solid-sate system, meaning that, according to one embodiment, it does not contain any solvents. According to an embodiment, the UV-curable lacquer may include three components: polymeric acrylate, photo initiator (PI), and an additive. Additives may be less than 5% weight of the entire lacquer substance, and may be added to increase or adjust certain properties of the lacquer material. These properties may include increased weathering ability or temperature stability, adhesion to the glass cover or substrate.

The photo-initiator (PI) may be less than 5% weight of the entire lacquer substance. The PI defines the hardening in dependence on the wavelength of the incoming irradiation. The advantages of such a system, include, but are not limited to fast hardening through UV-LED-radiation, very high molding accuracy, and stability in the nanometer band. In other words, the structure may be exactly the negative image used from the stamp in the printing process in which the holographic element is applied. Another advantage is very little shrinkage of the structure, temperature and weather stability, and improved adhesion to the glass slab or cover. These advantages may not be achievable through other means of forming the holographic structure, which may include electron beam hardening lacquers (ESH), which requires a high technical effort, cationic hardening lacquers, direct structuring of the glass substrate, and use of thermoplastics.

The process of manufacturing the solar module may include forming the holographic optical elements or structures by a roll-to-roll or a roll-to-plate printing process. In one embodiment, the holographic structures are 4-step diffractive optical elements (DOE). However, the holographic structures can have more or less than four steps, for example, 3 steps or five steps, or greater than 5 steps. Alternatively, the holographic structure may not include steps but rather be formed to smoothly transition in height along a smooth slope without steps.

However, according to one embodiment, the holographic structures have four steps. The four-step profile according to this embodiment, have a step height for each step of about 300 nm, or at least in the range of 200 nm to 400 nm, or in the range of 275 nm to 325 nm, or in the range of 290 to 310 nm. A step height of about 300 nm allows for wavelength selectivity. The use of more steps or less would result in a wider or narrower range of wavelengths that are diffracted. As silicon, which is often used as the detector material in the solar cell, may have a detection range of 100 nm to 1200 nm, 300 nm step heights yield good results.

In another embodiment, the visible part of the sunlight spectrum, for example, the light with wavelengths between about 400 and about 750 nm, may pass through the glass 12 and is bent by the holographic deflecting lens 14. This visible light is focused onto the silicon solar cell 16 in the manner previously explained. The solar module may also include, a germanium thermophotovoltaic cell 22 also mounted on the same board as the silicon solar cell, or at a different location. One or more other cell materials may also be used such as GaAs, CdS, and CdSe instead of or together with Ge.

According to one embodiment, the invisible light with higher wavelengths above 750 nm, including infrared light, isdeflected to the thermophotovoltaic cell. The infrared light passes through the glass 12 and the holographic deflecting lens 14 formed thereon and the heat from the higher wavelength light is converted by the germanium (or other suitable material) thermophotovoltaic cell 22 into electrical current. Through the usage of a germanium cell the heat is used instead of being wasted and the efficiency of a solar module, employing the solar cell and the thermophotovolatic cell 22, as a whole is increased.

According to another embodiment, the invisible light 30 with higher wavelengths above 750 nm, including infrared light 20, is deflected so that it is focused on the thermophotovoltaic cell 22. The holographic deflecting lens 14 is adapted to focus the higher wavelength light away not only away from the solar cell 16 as depicted in FIGS. 2 and 3, but to also focus such light onto the thermophotovoltaic cell 22 in order to use the solar light to the maximum efficiency.

An optimal light wavelength area using a silicon solar cell may be from 500 nm to 750 nm.

Solar cell 16 may be a metal wrap through (MWT) solar cell or an interdigitated back contact (IBC) solar cell. Both types of solar cells are possible to use in the solar module. Solar cell 16 may alternatively be a standard crystalline solar cell. Solar cell may alternatively be an emitter wrap through (EWT), a monocrystalline or polycrystalline solar cell.

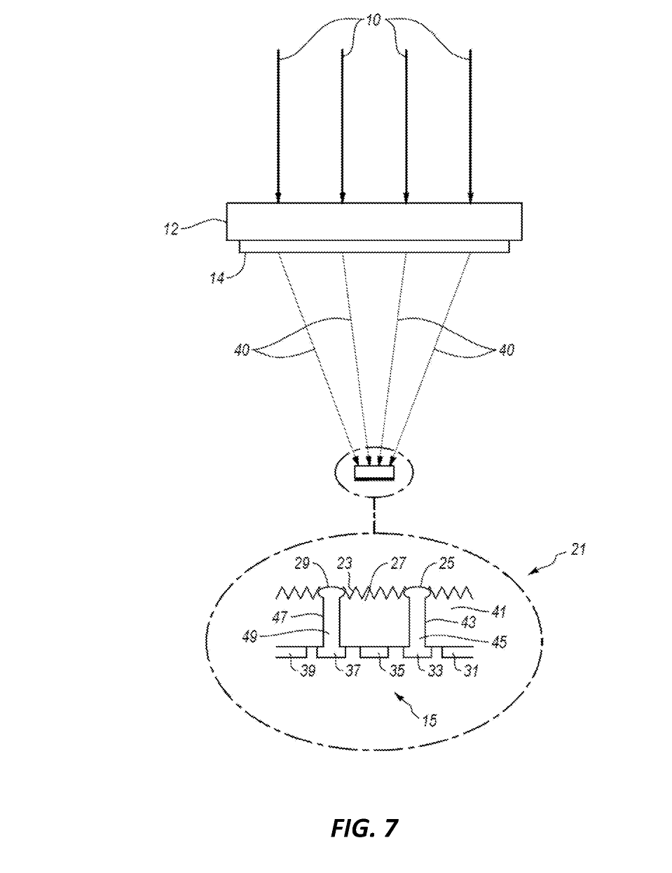

As shown in FIG. 7, the metal wrap through (MWT) solar cell 21 having contacts for the electrical interconnection on the back of the solar cell, on the side of the solar cell opposite from the glass slab 12 and lens 14. Therefore, the front contacts 25, 29, which are formed on passivated surface 23 facing toward lens 14, are connected to the back contacts, in this example, n-type contacts 33, 37, by metalized conductors 45, 49, formed in via holes 43, 47, respectively. Although passivated surface 23 is shown with periodic corrugations, the surface passivation is not limited to nor does it require periodic corrugations, and may include other means of surface passivation, such as laminate films formed thereon having differing reflectivity characteristics. Via holes 43, 47 are formed through p-type silicon base 41. In this embodiment, p-type contacts 31, 39 are also formed on the back surface of solar cell 16.

In result the MWT solar cell 21 has an advantage in efficiency due to reduced optical shading on the front of the solar cell 16, while the production cost are not higher compared to standard solar cells. The interconnection with the solar module can be realized with structured cell connectors or conductive back foils.

MWT cells with high efficiency are a viable solution provided that the stresses caused by drilling the via holes to the silicon do not cause extensive cracking or stress that prevent the cutting process.

In this example, each cell is 156×156 mm and has a minimum of 60 via holes and possibly up to 400 via holes. The hole-size has to be very small (100 um) and the stresses caused by drilling the vias are kept to the minimum to enable cutting of the cells.

Further, the pad size and feature alignment has to be small enough to ensure a low level of optical shading and in result high efficiency.

A MWT-PERC (Passivated Emitter Rear Contact) cell would give 1-2% (absolute) higher efficiency and the cell should have a development path to enable that in the future.

The metallization should not continue from one sub-cell to the next. The front metallization grid should be double-printed to have sufficient amount of metal to carry the current with low ohmic losses.

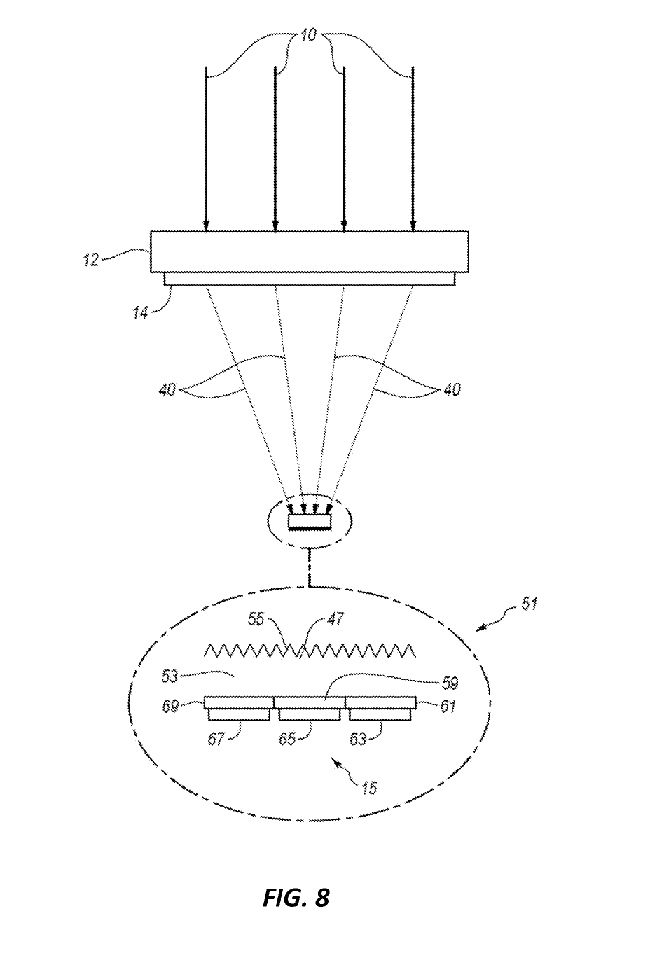

As shown in FIG. 8, solar cell 16 includes interdigitated back contact (IBC) solar cell 51, having passivated layer 55 having anti-reflection coatings formed on the surface facing toward glass slab 12 and lens 14. An n-type diffusion layer 47 is formed on p-type substrate 53 along the passivated layer 55. In the IBC solar cell, back contact 15 includes positive contact 65 formed on the surface of the solar cell opposite from the passivated surface 55. Positive contact 65 is aligned with p-type diffusion layer 59. Also on the back surface of solar cell 16, back contact 15 further includes negative contacts 63, 67, which are aligned with n-type diffusion regions 61 and 69.

Rear contact solar cells, such IBC, eliminate shading losses altogether by putting both contacts on the rear of the cell. By using a thin solar cell made from high quality material, electron-hole pairs generated by light that is absorbed at the front surface can still be collected at the rear of the cell. Such cells are especially useful in concentrator applications where the effect of cell series resistance is greater.

An additional benefit is that cells with both contacts on the rear are easier to interconnect and can be placed closer together in the module since there is no need for a space between the cells.

Although in the exemplary embodiments, semiconductor conductivity types are describes, such are arrangements are not to be limiting, and differing conductivity type arrangements may also be employed.

IBC (Interdigitated Rear Contact) cell suits very well for solar module including the lens 14 arranged between the glass slab 12 and solar cell 12. In this type of cell both contacts are on the back of the cell. The contacts are lines, should have a small pitch (about 0.5 mm) and the contacts at both ends of the 78 mm long cell.

In this example, each unit cell is separated. The metallization should be stress free to ensure easy processing of the strips. The metallization should have sufficient amount of metal to carry the current with low ohmic losses. Ion implantation is recommended for the doping to ensure good tolerances.

In this and all embodiments of the disclosure, the glass slab 14 may be of a thickness ranging between 0.2 and 0.6 cm. In another embodiment, the glass slab 14 is about 0.3 cm in thickness.

As mentioned previously, the novel holographic deflecting lens 14 makes possible a solar module in which a very small distance is needed between the lens 14 and any of the silicon cells and thermophotovoltaic cells. This distance d is depicted in FIG. 3, but applies to all embodiments discussed herein. The distance d between the lens 14 and the back contact solar cell 16 (and any thermophotovoltaic cell) may range between 0.4 cm and 5.0 cm, depending on the concentration factor. According to one embodiment, distance d can range between 1.0 cm to 5.0 cm, depending on the concentration factor. According to another embodiment, the distance d may be no greater than 1.1 cm, and or no greater than 0.5 cm. The distance d according to another embodiment ranges between 0.4 cm and 1.1 cm, or between 0.5 and 1.0 cm, and or between 0.5 cm and 0.7 cm. This in turn imparts a very small overall module height and cost friendly production. Consequently, compared to traditional solar panels, a significantly reduced cost of constructing and transporting is achieved.

As mentioned previously, the holographic deflecting lens 14 is uniquely adapted to selectively concentrate, deflect, and focus different components of the solar spectrum. As also just discussed, the same lens 14 is uniquely adapted to selectively deflect some light components from lower wavelength light, including ultraviolet light, into a particular range of visible light wavelengths. Thus a solar module, according to one embodiment, is configured to manage impinging light, which means the solar module, due to the holographic lens, is configured to select, deflect, and concentrate different wavelengths of light according to the characteristic of the light to ensure the maximum efficiency of the solar module converting the impinging light into electrical energy.

The holographic lens 14 is a single-layered system with very fine lens structures that are adapted with precision to selectively bend and/or deflect each different light component according to the wavelengths of light that are included in that light component. This not only enables the need for a minimal amount of silicon and other solar cell material to produce high amounts of electrical energy, but the single-layered nature of the holographic deflecting lens 14 also imparts simple duplicability to the lens as a whole. Conventional holographic grids are manufactured by repeated steps of coating, exposing, and developing films or foils. The foils are laminated to a holographic foil cluster, and in a conventional system four or more foils are laminated to one foil. This manufacturing method is expensive because it requires a lot of machinery and is extremely slow.

In contrast, the holographic deflecting lens 14 may be a printed hologram that is a grid structure, but differs from a holographic grid, which has to be costly exposed with each manufacture as described above. Instead, the deflecting surface release structure of the present disclosure can be repeatedly duplicated almost any number of times. This new method includes printing the hologram on the glass 12 of the module in a roll-to-roll process. In another embodiment, the hologram may be printed on the glass in a roll-to-place process. The hologram may be printed, and may be a polymer material which is printed in one single printing step. Furthermore, the hologram is a single layer that is printed in one simple rolling print process. It is not necessary to coat, expose and/or develop the foil. Because of the simplicity and the single print rolling step nature of this method, the holographic deflecting lens 14 can be replicated on the inner side of the glass slab 12.

The holographic deflecting lens 14 may be made from silicone or a hardened UV-glue or UV lacquer or Polymethylmethacrylate (PMMA). The production of a foil, which has the surface relief on one side, is also possible due to the nature of the lens 14. The foil may also be affixed on the glass 12 or laminated thereon. Accordingly, the glass 12 can function as support material for the holographic deflecting lens 14 and it protects the lens 14 from destructive environmental influences.

It is of value to next explain some other advantages of the present solar modules when compared to conventional systems that incorporate Fresnel lenses. Sunlight in all of its wavelengths is broken and magnified many hundreds of times with a Fresnel lens without selectivity of any particular wavelengths. Because even infrared light and ultraviolet light are broken and magnified, several disadvantages are inherent in Fresnel lens modules. The heat created by magnification of all of the sunlight wavelengths, including infrared light, creates an enormous amount of heat. Consequently, conventional solar modules must be equipped with some sort of cooling system to avoid early wear and destruction of the solar module components including the semiconductor material, as well as the solar panel as a whole. Furthermore, a Fresnel lens has a relatively large focal length of up to 20 cm, and this in turn produces modules that are quite thick. These large structures result in solar power units that are very heavy.

In contrast, the solar modules of the present disclosure treat different sunlight components differently according to the wavelengths of light included in each component. Exemplary solar modules according to one embodiment of the present disclosure include the holographic deflecting lens 14 that is adapted to bend and concentrate a selected component of light having a specific wavelength range, for example, light in the wavelengths ranging between about 380 and about 1150 nm (including visible light and near infrared (NIR) light or between about 500 and about 750 nm, or ranging between 500 and 600 nm, or ranging between 510 and 580 nm, and concentrate that light onto the solar cell 16. Thus, because the light is bent and concentrated instead of being broken and magnified with a Fresnel lens, the distance d between the lens 14 and the solar cell 16 may be between 0.4 to 5.0 cm, depending on the concentration factor. In one embodiment, distance d may range from 1.0 to 5.0 cm, depending on the concentration factor. In another embodiment, distance d may range from 0.4 cm to 0.5 cm, depending on the concentration factor.

Furthermore, because the higher frequency light component, including infrared light, is either reflected away from the solar cell 16 according to one embodiment, or is selectively bent and concentrated onto a thermophotovoltaic cell according to another embodiment, using the same holographic lens 14, no cooling structure needs to be included in the solar module of the present disclosure.

Finally, because the lower frequency light component, including ultraviolet light, is either reflected away from the solar cell 16 according to one embodiment, or is deflected toward a different solar cell capable of converting ultraviolet light or light of the lower frequency to electrical energy, it is possible to produce electricity from essentially the entire sunlight spectrum with a single holographic lens 14 without any Fresnel lens, any additional holographic lens, or any other lenses of any type included in the solar module. In other words, the solar module is a single-lens system in which the only lens that is used is the deflecting holographic lens 14 that is directly fixed on and supported by the glass slab 12. Furthermore, a solar module incorporating such solar cells consists of the single-lens holographic lens 14.

According to an embodiment, the holographic structure is formed by a method including roll-to-roll or roll-to-plate printing process. According to the method a negative structure is formed in a master foil. The master foil may be a roll or cylindrical shape or have a plate or planar shape. The negative structure may be formed in the master foil by various means. The negative structure may be formed in the master foil by e-beam lithography. The foil may have a thickness of 3 micrometers. The negative structure can be formed to directly correlate with the 4-step structure of the holographic structures. The foil itself may be formed of a metal material, alloy, or polymer material, or a ceramic material, or any other material that may be used in a printing process to transfer a printed structure.

Then, uncured lacquer may be applied to the master foil and then transferred to the surface of the glass slab or cover. The lacquer may be applied by slot die coating. Air bubbles may form in the lacquer due to misalignment. Setting appropriate parameters may yield smooth lacquer film thickness of about 10 micrometers. A web may be unrolled, for example, from left to right, and the web is rolled over a pressure and embossing roller having the mater foil. The liquid lacquer on the web may then be UV-cured and reeled form the embossing roller. Then, upon UV-curing, or other means of curing, the structure web having the holographic structures formed thereon can be reeled up. Subsequently, the web having the holographic structures can be unrolled and incorporated into a solar module as described above, wherein the holographic structures are aligned with the detection material of the respective solar cells, with each solar cell extending in a stripe form corresponding with one of the strips of the holographic optical element.

In another embodiment, the diffractive holographic optical element is formed by forming a pattern of a diffractive optical cylinder lens by e-beam into resist on a silicon wafer. The pattern is then transferred into the silicon by dry etching. With several e-beam lithography steps and etching processes, a multi-level diffractive optical lens is formed. For example the multi-level may have two, four, or eight different levels. The silicon wafer with the diffractive holographic element is then used as a master. From the master patter, a flexible transparent stamp is fabricated by using a polymer foil together with a UV-curable resist. After UV curing the stamp foil is demolded from the master. The stamp foil may then used to imprint and UV cure the pattern into a resist on the transparent cover. This process can be scaled-up into volume production by a roll-to-plate imprint process.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure, it being understood that various changes may be made in the function and arrangement of elements described in an exemplary embodiment without departing from the scope of the disclosure as set forth in the appended claims and their legal equivalents.

What is claimed is:

1. An energy conversion device comprising:
a multi-step holographic optical element arranged between a transparent cover and a first solar cell, wherein
the multi-step holographic optical element is configured to concentrate a portion of a first component of impinging electromagnetic radiation onto the first solar cell, and
the solar cell is configured to convert the first component of impinging electromagnetic radiation into electrical energy.

2. The energy conversion device according to claim 1, wherein the multi-step holographic optical element includes a four-step holographic structure having four steps, each of the four steps raising in height in a direction perpendicular to a surface of the transparent cover.

3. The energy conversion device according to claim 1, wherein the transparent cover includes a glass layer.

4. The energy conversion device according to claim 1, wherein the multi-step holographic optical element is printed directly on the transparent cover.

5. The energy conversion device according to claim 2, wherein the multi-step holographic optical element includes
a central multi-step holographic structure,
a first peripheral multi-step holographic structure and a second peripheral multi-step holographic structure, the first and second peripheral multi-step holographic structures being formed on opposite sides of the central multi-step holographic structure in a direction parallel to a surface layer of the transparent cover,
a first lateral multi-step holographic structure formed between the central multi-step holographic structure and the first peripheral multi-step holographic structure, and
a second lateral multi-step holographic structure formed between the central multi-step holographic structure and the second peripheral multi-step holographic structure.

6. The energy conversion device according to claim 1, wherein the multi-step holographic optical element includes a plurality of steps in a holographic structure, each of the steps having a height of about between 200 nm to 400 nm in height in a direction perpendicular to a surface of the transparent cover.

7. The energy conversion device according to claim 1, wherein the multi-step holographic optical element includes a plurality of steps in a holographic structure, each of the steps having a height of about between 250 nm to 350 nm in height in a direction perpendicular to a surface of the transparent cover.

8. The energy conversion device according to claim 1, wherein the multi-step holographic optical element is formed from a material including a UV-curable polymer.

9. The energy conversion device according to claim 5, wherein the total width of the multi-step holographic optical element is between 2 cm and 4 cm, and the multi-step holographic optical element extends as a stripe in a direction along a surface of the transparent cover in a same direction as the solar cell, the solar cell also extending as a strip in the direction along the surface of the transparent cover, the width of the solar cell being less than the width of the multi-step holographic optical element.

10. The energy conversion device according to claim 9, wherein the holographic optical element has a concentration factor of a variable X, and the width of the holographic optical element is greater than the width of solar cell by the variable X.

11. The energy conversion device according to claim 1, wherein the multi-step holographic optical element directs a portion of a second component of the electromagnetic radiation away from the first solar cell.

12. The energy conversion device according to claim 1, wherein the multi-step holographic optical element is essentially the only light-deflecting element included in the energy conversion device.

13. The energy conversion device according to claim 1, wherein the multi-step holographic optical element consists of a single holographic layer.

14. The energy conversion device according to claim 1, wherein the multi-step holographic optical element is formed from a material including an acrylate polymer.

15. The energy conversion device according to claim 1, wherein the multi-step holographic optical element is formed from a material that includes a UV-curable polymer, a photo initiator, and an additive.

16. The energy conversion device according to claim 11, wherein
the first component of the electromagnetic radiation includes visible light or visible light and near infrared light, and
the second component of the electromagnetic radiation includes at least one of infrared light and ultraviolet light.

17. The energy conversion device according to claim 1, wherein the multi-step holographic optical element is printed directly onto the transparent cover.

18. The energy conversion device according to claim 1, further comprising
a second solar cell arranged at a position different than the first solar cell,
wherein the multi-step holographic optical element is configured to concentrate the portion of the second component of the electromagnetic radiation onto the second solar cell, and
wherein the first solar cell is photovoltaic cell, and the second solar cell is a thermophotovoltaic cell.

19. The energy conversion device according to claim 1, wherein the energy conversion device is configured to deflect a portion of a second component of impinging electromagnetic radiation from to concentrate a portion of the second component of the electromagnetic radiation onto a second solar cell configured to convert the second component of the electromagnetic radiation into electrical energy.

20. A method of making an energy conversion device, the method comprising:
roll printing a multi-step holographic optical element directly onto first surface of a transparent in a pattern that forms a holographic lens;
arranging the holographic lens between the glass slab and a first solar cell; and
arranging the first solar cell such that at least one solar cell stripe of the first solar cell is arranged between the holographic lens and an electrical connector, the electrical connector being electrically connected to the at least one solar cell stripe.
